(19) United States
(12) Patent Application Publication
(10) Pub. No.: US 2011/0272179 A1
(43) Pub. Date: Nov. 10, 2011

(54) Printed Circuit Board with Embossed Hollow Heatsink Pad

(76) Inventor: Kalu K. Vasoya, Yorba Linda, CA (US)

(21) Appl. No.: 13/095,799

(22) Filed: Apr. 27, 2011

Related U.S. Application Data
(60) Provisional application No. 61/332,109, filed on May 6, 2010.

(51) Int. Cl. H05K 7/20; H05K 3/02

(52) U.S. Cl. 174/252; 29/846

(57) ABSTRACT

A printed circuit board includes a dielectric layer having a first surface and an opposing second surface and a circuit layer laminated to the first surface of the dielectric layer. Cut-out windows provide openings through the dielectric and circuit layers. A thermally conductive layer is laminated to the second surface of the dielectric layer. The thermally conductive layer includes at least one sinkpad that passes through the cut-out windows. The sinkpad is an embossed, hollow feature of the thermally conductive layer. A surface of the sinkpad may be substantially coplanar with a surface of the circuit layer and be prepared for compatibility with a solder reflow process. A heat generating electronic component may be electrically coupled to the circuit layer and thermally coupled to the sinkpad of the thermally conductive layer to form an electronic assembly.

### CROSS REFERENCE TO RELATED APPLICATIONS

This application claims the benefit pursuant to 35 U.S.C. 119(e) of U.S. Provisional Application No. 61/332,109, filed May 6, 2010, which application is specifically incorporated herein, in its entirety, by reference.

### BACKGROUND

1. Field

Embodiments of the invention relate to the field of means for dissipating heat from electronic components; and more specifically, to printed circuit boards including a heat conducting means for cooling devices mounted to the printed circuit board.

2. Background

With the coming of energy-saving era, high power (HP), high bright (HB) light-emitting diodes (LEDs) are promising to replace other technologies such as incandescent and fluorescent bulbs in signaling, solid state lighting, vehicle headlight and many more evolving applications due to improved luminescent efficiencies and extended lifetime. Power dissipation ratings ranging from 500 mW to as much as 25 watts in a single package have become a standard and are expected to increase in the future.

However, current packaging efficiencies clearly indicate that conventional packages are inadequate for the demands of many current and future applications. Heat accompanied by higher power higher brightness not only causes efficiencies to lower down, but also influences long-term reliability of LED devices. Consequently, thermal management of high power LEDs is extremely crucial for proper operation and extended life.

Optimal heat dissipating material and package method should be well designed to fit the growing power needs. The key to a successful design starts with the transfer of LED heat. Each custom LED lighting design involves the concept of efficiently transferring as much heat as possible away from LED PN junction.

The process begins within the LED lamp, where thermal energy released into an integrated thermal slug can potentially exit the light emitting diode. Modern surface mount LED lamps depend on the thermal efficiency of this slug. Traditional though-hole LEDs actually produce much less heat and can dissipate some into the actual wire leads. Other surface mount LED lights rely on their power and ground pads to dissipate the heat. In some LED packages thermal slug is electrically isolated from the P-N leads where as in many packages thermal slug is electrically not isolated from the P-N leads. The slug found in modern LED lamps requires a secure bond with an underlying circuit board pad to provide an efficient means of heat transfer out of the LED lights.

There are various printed circuit board approaches commercially available to improve heat dissipation. The metal base or metal core printed circuit board (MCPCB) such as IMS™ “Insulated Metal Substrate”. IMS™ type boards are manufactured by several manufacturers around the globe such as Thermal Clad™ by The Bergquist Company, T-lam™ by the Laird Technologies, CooLam by Dupont and HITT plate boards from Denka. These MCPCB is made of a layer of a heat spreading material such as aluminum, copper or alloys thereof laminated with the layer of dielectric material and circuit layer to act as a heat spreader for the heat generated from the hot LED.

Typical IMS construction has a dielectric layer between a circuit layer and a heat spreader layer. This dielectric layer as it stands for provides electrical isolation between circuit layer and heat spreader layer. More often these MCPCBs utilize thermally conductive dielectric to reduce thermal resistance between LED and a heat spreader layer. Thermally conductive dielectric require addition of thermally conductive particles which is more expensive. Even though vast amount of work has been done to improve thermal performance of such dielectric layer it is still the least thermally conductive medium between LED and the heat spreader. Thermal resistance of the thermally conductive dielectric is only as good as its thermal conductivity. Typical thermal conductivity of the thermally conductive dielectric material is about 1.0 to 4.0 W/m.k. Also dielectric layer must be thick enough to ensure it is void free with appropriate electrical insulation, adding to thermal resistance. Thus, current IMS™ approach is not sufficient enough to efficiently remove heat from some of the high power high bright LEDs.

A commercially available metal back printed circuit board MCPCB assembly is shown in FIG. 2. As illustrated, the metal back printed circuit board assembly 210 comprises of a metal layer 220, thermally conductive dielectric layer 229, electrical circuit pad 228, plurality of components 242; 244 and 246, electrical connections 248; 250 and 252 respectively and thermal interface material 254. The thermal pad or bond pad 218 is acting as a thermal drain to conduct heat away from hot LED to the thermally conductive dielectric 229, from thermally conductive dielectric layer 229 to the metal layer 220 then to the additional heat sink or atmosphere. Undesirable high thermal resistance paused by the dielectric layer between the heat source and the metal layer.

Other approach includes fiber glass PCB with thermal vias (drilled holes that are plated with copper) to conduct heat better through vertical direction, metal core printed circuit board (MCPCB) with cavity. Example of such systems are disclosed in Patent Numbers EP1,881,746A2; U.S. Pat. Nos. 7,505,275; 7,365,988; 6,921,927 and 6,428,189. Metal core PCB with cavity approach provides lowest thermal resistance. However, cavity MCPCB requires custom LED design such that PN leads come out from bottom up so that body of the LED sits into cavity and leads gets soldered to the top circuit layer.

Another commercially available metal back printed circuit board MCPCB assembly with cavity is shown in FIG. 3. As illustrated, the metal back printed circuit board assembly 310 comprises of a metal layer 320, a dielectric layer 329, electrical circuit pad 328, plurality of components 342; 344 and 346, electrical connections 350 with circuit pad 328 and thermal interface material 354. The cavity through the dielectric layer 319 is allowing hot LED to thermally couple directly with the metal layer 320 via a thermal interface material 354. Heat flows from the hot LED component to the metal layer 320 then to the additional heat sink or atmosphere. Since thermal coupling is at the bottom of the cavity and electrical coupling at the top of the cavity undesirable custom physical structure of the LED component required. A thermal coupling surface and an electrical coupling surface are not coplanar with each other.

There are other commercially available thermal boards such as Anotherm™ boards from TT Electronics. It uses a thin anodization layer on top of the aluminum layer. The use of anodization as the dielectric layer provide better thermal conduction but forces the use of aluminum as its heat spreader layer, since copper can not be anodized. Since the thermal conductivity of aluminum is substantially less than copper and other metal, this can be a thermal disadvantage. Thus this concept is very limited in its practical use.

All of the foregoing approaches provides poor thermal coupling between heat source and heat sink or heat spreader raising LED junction temperature.

It would be desirable to provide a printed circuit board that provides good thermal coupling between a heat source in the form of an electrical component mounted to the printed circuit board and a heat sink or a heat spreader that is part of the printed circuit board.

### SUMMARY

Thermal management of high power LEDs is extremely crucial for proper operation and extended life. Optimal heat dissipating material and package method should be well designed to fit the growing power needs. Typically, LEDs are encapsulated in a transparent resin, which is a poor thermal conductor. Nearly all heat produced is conducted through the back side of the chip. Thus, heat is generated from the PN junction and conducted to outside ambient through a long and extensive path. Typical path in MCPCB of the prior art heat flows from junction to thermal slug, thermal slug to underlying circuit board pad, from underlying circuit board pad to heat spreader via thermally conductive dielectric material, from heat spreader metal layer to additional heat sink and/or to the atmosphere. Thus ability to conduct heat from LED to atmosphere is limited by the thermal resistance of the dielectric material located between circuit layer and a heat spreader layer. Electrical circuit pad and thermal pad are not coplanar in a Cavity MCPCB, adds limitation in surface mount type LED component mounting.

Present invention overcomes these limitations. Printed wiring board of the present inventions having a layer stack-up includes a circuit layer, a dielectric or electrical insulating layer and a thermally conductive layer which has “heatsink pad”. The heatsink pad is formed onto thermally conductive layer in a surface normal to the surface spreading direction of the thermally conductive layer, an opening is formed onto a dielectric layer, and an opening is formed onto a circuit layer. The openings and heatsink pad are aligned such that heatsink pad extends through the circuit layer and dielectric layer opening. The height of the heatsink pad normal to the surface spreading direction of the thermally conductive layer prior to the lamination process is equal to more than the total thickness of the circuit layer and the dielectric layer. The heatsink pad is hollow in its cross-section. The material used for a thermally conductive layer is rigid however it can conform or change its original shape under pressure. The hollow nature of the heatsink pad and the conforming nature of the thermally conductive material allows heatsink pad to get compressed under pressure during lamination process making it consistent coplanar with the circuit layer. Where later LED gets thermally coupled with heatsink pad and electrically coupled with the circuit pad. Since heatsink pad is the formed portion of the thermally conductive layer there is no additional thermal resistance between the heatsink pad and the thermally conductive layer. In the present invention heat flows from the PN junction to a thermal slug, thermal slug to an underlying heatsink pad, heatsink pad to the thermally conductive layer, thermally conductive layer to additional heat sink and/or to the atmosphere. Heatsink pad is a continuous form of the thermally conductive layer in a direction normal to the surface spreading direction of the thermally conductive layer. Thus completely eliminating thermal resistance paused by the dielectric material located between the circuit layer and thermally conductive layer as described in the prior art. Going forward we will call “heatsink pad” a “sinkpad” for simplicity. The present invention has been proposed under the circumstances described above, and therefore aims at providing a thermally efficient printed wiring board which can be formed with the sinkpad. Where sinkpad is coplanar with the outermost circuit layer and later LED component can be thermally coupled directly with the sinkpad.

Processes for manufacturing thermally efficient printed wiring boards including sinkpad as a part of the thermal drain are disclosed. Processes in accordance with the present invention enable heat from the LED conduct away to the thermally conductive material via sinkpad. In other embodiment present invention enable least thermal resistance between heat source and surrounding atmosphere.

In one embodiment of the present invention sinkpad surface is coplanar with the outermost circuit layer surface.

In another embodiment, sinkpad surface is lower than the outermost circuit layer surface.

In a further embodiment, sinkpad surface is higher than the outermost circuit layer surface.

In one of the most preferred embodiment, sinkpad is hollow in its cross-section as shown in FIG. 1.

In several embodiments, electrical coupling of the LED component with the circuit pad and thermal coupling of the LED component with the sinkpad are coplanar.

In several other embodiments, coplanarity between circuit pad and sinkpad is within +/−3 mil tolerance.

In one embodiment, dielectric layer does not need to be a thermally conductive.

In one preferred embodiment, dielectric materials are prepreg and clad or unclad laminate, where prepreg is low-flow or no-flow type prepreg;

In one embodiment of the present invention sinkpad is a formed portion of the thermally conductive layer where sinkpad is a continuous part of the thermally conductive layer;

In another embodiment of the present invention sinkpad is formed onto the thermally conductive layer where sinkpad is made from a first material composition and the thermally conductive material is made from second material composition where first and second materials are thermally conductive;

In one embodiment of the present invention LED is thermally coupled with the sinkpad surface of the thermally conductive layer;

In another embodiment, plurality of LEDs are thermally coupled with thermally conductive layer via sinkpad;

In one embodiment of the present invention thermal coupling between the LED and a sinkpad is made using thermally and electrically conductive material;

In other embodiments of the present invention thermal coupling between the LED and a sinkpad is made using thermally conductive material where thermally conductive material is not electrically conductive;

In one embodiment of the present invention method of manufacturing includes data preparation of defining location of the sinkpad and preparation of necessary tool.

Preferably, sinkpad on the thermally conductive layer is formed using forming method.

More preferably, sinkpad on the thermally conductive layer is formed using embossing method.

In one preferred embodiment of the present invention sinkpad forming is done using a male-female punch and die.

In one most preferred embodiment sinkpad forming is done using CNC turret press.

In several other embodiments sinkpad on the thermally conductive layer is formed using stamping process, molding process, casting process, forging process, welding process or tight press-fit process.

In one preferred embodiment of the present invention thermally conductive layer is rigid.

In one more preferred embodiment of the present invention thermally conductive layer is rigid and can be formed under force to change its original shape.

In one most preferred embodiment of the present invention any malleable thermally conductive material that can be formed as required by the invention can be used for the thermally conductive layer.

In one embodiment, thermally conductive layer can be made from a thermally conductive metal.

In other embodiments, metal can be aluminum, nickel coated aluminum, copper coated aluminum, copper, ferrous, non-ferrous, aluminum graphite composite, metal matrix cast composite or any combination of metal and composite.

In one more embodiment, thermally conductive layer can be made from thermally conductive nano materials.

In one embodiment, thermally conductive material can be made from carbon.

In other embodiment, thermally conductive material can be made from graphite.

Other features and advantages of the present invention will be apparent from the accompanying drawings and from the detailed description that follows below.

### BRIEF DESCRIPTION OF THE DRAWINGS

The invention may best be understood by referring to the following description and accompanying drawings that are used to illustrate embodiments of the invention by way of example and not limitation. In the drawings, in which like reference numerals indicate similar elements:

FIG. 1 is a schematic cross section of a thermally efficient printed wiring board assembly constructed in accordance with an embodiment of the present invention that includes LED component thermally coupled with a thermally conductive layer via hollow sinkpad.

FIG. 2 is a schematic cross section of one of the prior art metal back printed wiring board assembly where LED component is thermally coupled with base metal via a dielectric layer and a thermal pad.

FIG. 3 is a schematic cross section of another prior art metal back printed wiring board assembly with cavity approach where LED component is thermally coupled with metal layer.

FIG. 4 is a flow chart illustrating a process for manufacturing a thermally efficient printed wiring board in accordance with one of the preferred embodiment of the present invention.

FIG. 5 is a cross sectional view of one of the LED component.

FIG. 6 is a schematic top view of a outermost circuit layer in accordance with an embodiment of the present invention where sinkpad locations are defined.

FIG. 7 is a schematic view of an embossing and/or forming male-female die in accordance with an embodiment of the present invention that is used to form sinkpad onto the thermally conductive layer.

FIG. 8 is a schematic view of another embossing and/or forming male-female die in accordance with an embodiment of the present invention that is used to form sinkpad onto the thermally conductive layer.

FIGS. 9A-9K are schematic cross-sectional views of various thermally efficient printed wiring board subassemblies that are constructed as part of the manufacturing process illustrated in FIG. 4.

FIG. 10 is a schematic cross-sectional view of another thermally efficient multilayer printed wiring board assemblies that is constructed in accordance with the present invention.

FIG. 11 is a schematic cross-sectional view of yet another thermally efficient multilayer printed wiring board assemblies that is constructed in accordance with the present invention.

### DETAILED DESCRIPTION

In the following description, numerous specific details are set forth. However, it is understood that embodiments of the invention may be practiced without these specific details. In other instances, well-known circuits, structures and techniques have not been shown in detail in order not to obscure the understanding of this description.

Turning now to the drawings, embodiments of the thermally efficient printed wiring board process that include at least one sinkpad acts as thermal drain in accordance with the present invention are shown.

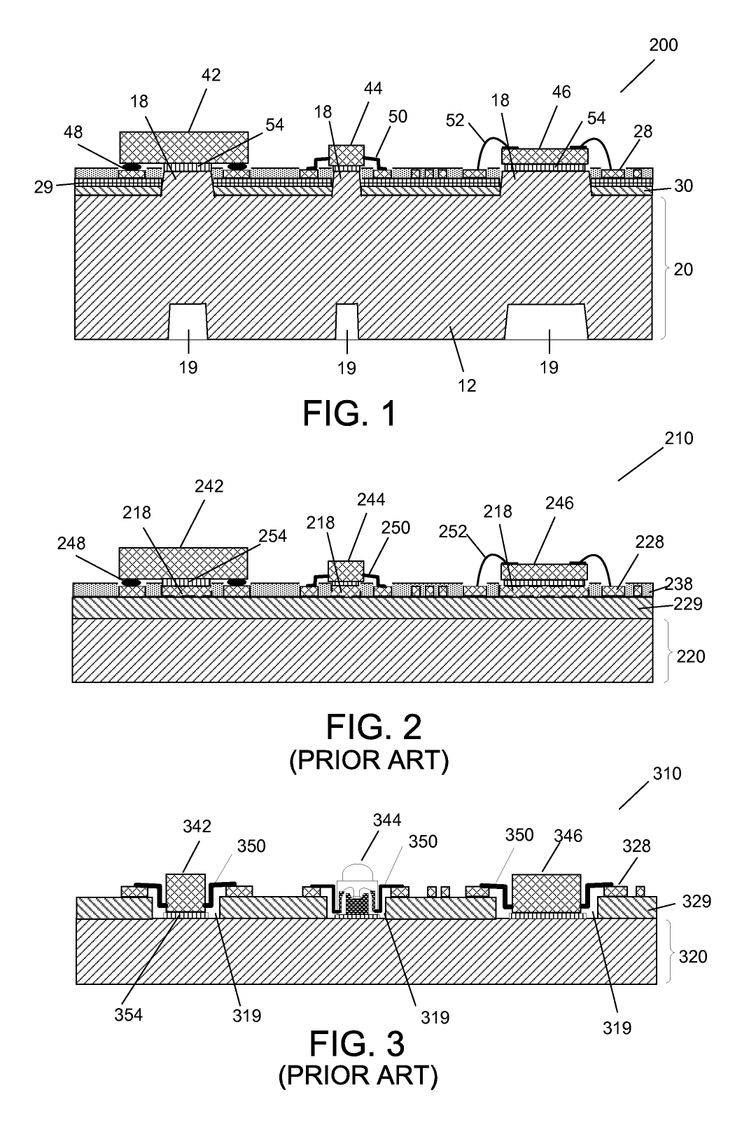

One of the preferred embodiments of a thermally efficient printed wiring board assembly in accordance with the present invention is shown in FIG. 1. As illustrated, the thermally efficient printed wiring board assembly 200 comprises a thermally conductive layer 12 on which plurality of hollow sinkpads 18 are formed in a direction normal to the surface spreading direction of the thermally conductive layer 12, sinkpad base 20, dielectric layer 30, electrical circuit pad 28, plurality of components 42, 44 and 46, electrical connections 48, 50 and 52 respectively and thermal interface material 54. The term “hollow sinkpad” is used in this specification to mean a sinkpad 18 that raised above the surrounding surface of the thermally conductive layer 12 with a corresponding depression 19 in the opposite surface of the layer that creates a void or “hollow” in the cross-section of the sinkpad The sinkpad 18 is acting as a thermal drain to conduct heat away from the hot LED to the thermally conductive layer of the thermally efficient printed wiring board and then to an additional heat sink or ambiance.

A variety of techniques can be used to form a sinkpad onto the thermally conductive layer. One of the preferred sinkpad forming methods is an embossing method, and more preferably a half-shear type of embossing. The embossing process can be performed using a hard tooling press method or a CNC turret press method. Prepare dielectric layer and circuit layer according to the design. Dielectric layer can be semi-cured B-stage prepreg preferably which has low flow characteristic. Stack, align and laminate embossed thermally conductive layer, a dielectric layer and a circuit layer together. Finish printed circuit board processes. Assemble LED component on to the thermally efficient printed wiring board where the LED gets electrically coupled with the circuit pad and thermally coupled with the sinkpad surface. Thermal interface material can be used to thermally connect LED component with the sinkpad surface.

Although the embodiment shown in FIG. 1 includes a single circuit layer, embodiments of the invention can include multiple circuit layers as shown in FIG. 10 and FIG. 11.

A thermally conductive layer that has a solder compatible component interface surface is advantageous and preferred in present invention. It enables a hot component to thermally couple directly with the thermally conductive layer by means of solder; which in turn brings minimum thermal resistance between hot component and the thermally conductive layer. However, some thermally conductive materials, for example aluminum, do not have a solder compatible surface. In such case additional surface preparation is necessary.

Manufacturing a Thermally Efficient PWB that has an Embossed Sinkpad

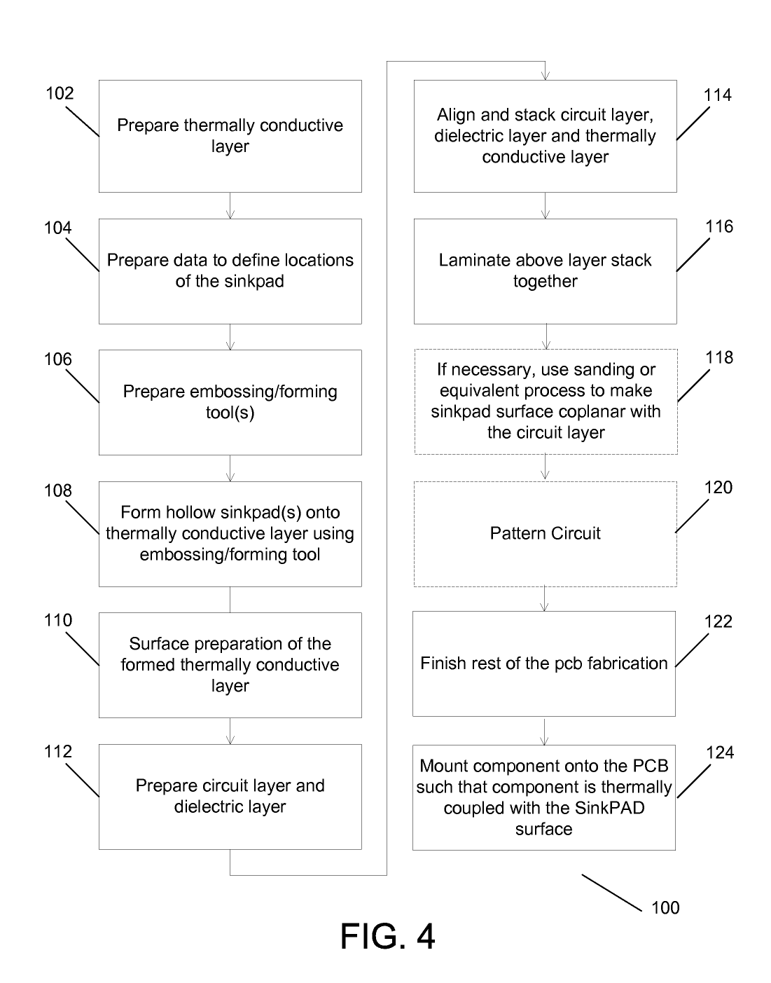

A process for constructing a thermally efficient PWB in accordance with an embodiment of the present invention is illustrated in FIG. 4. The process 100 includes preparing a thermally conductive layer (102) which will be used further to form a sinkpad. Prepare data to define locations of the sinkpad (104). Data preparation (104) includes review a circuit design, specify sinkpad shape and size, add sinkpad features at each LED Component locations are such that later LED component can be thermally coupled with the sinkpad surface for the optimum conduction thermal path. Data preparation (104) also includes output sinkpad features to prepare for embossing and/or forming tool.

Prepare embossing and/or forming tool (106) as per data. In a number of embodiments, embossing tools are made of a male-female die. In one embodiment a tool includes several sinkpad features at least equal to the total number of sinkpad features on a single printed circuit board where all the sinkpad are embossed at once. In one preferred embodiment a tool includes fewer sinkpad features than the total number of sinkpad features on a single printed circuit board, preferably one sinkpad feature per tool. In one preferred method a CNC turret press can be used to emboss the sinkpad feature. Form (108) a hollow sinkpad onto the thermally conductive material using the embossing tool. There may be a surface preparation (110) of the formed thermally conductive material to enhance compatibility with solder processes and/or bonding with the dielectric layer.

Prepare a dielectric layer and a circuit layer. A dielectric layer can be semi-cured B-stage prepreg preferably which has low flow or no flow characteristic. A circuit layer can be a copper foil or a copper clad laminate. Prepare the circuit layer and the dielectric layer (112). Preparation of the dielectric layer includes removing a portion of the dielectric material at the predefined locations. Preparation of the circuit layer in the case of clad laminate includes patterning the circuit pattern and removing a portion of the copper clad laminate at the predefined locations. The circuit pattern process on a circuit layer may be postponed until after a lamination process (116) is completed.

Preparation of the circuit layer in the case of foil includes removing a portion of the foil at the predefined locations. Align and prepare (114) a stack of the formed thermally conductive layer, a dielectric layer and a circuit layer. Laminate (116) stacked layers together under pressure and temperature for defined period of time. If necessary, use sanding, grinding, scrubbing, co-planarization or an equivalent process (118) to make an uneven sinkpad height coplanar with the circuit layer. Pattern circuit on a circuit layer (120) if it was not done in the step (112). Apply solder mask, surface finish, fab, test and finish (122) thermally efficient printed wiring board of the present invention. Assemble (124) LED component onto the thermally efficient printed wiring board such that LED is electrically coupled with the electrical circuit pad and thermally coupled with sinkpad surface.

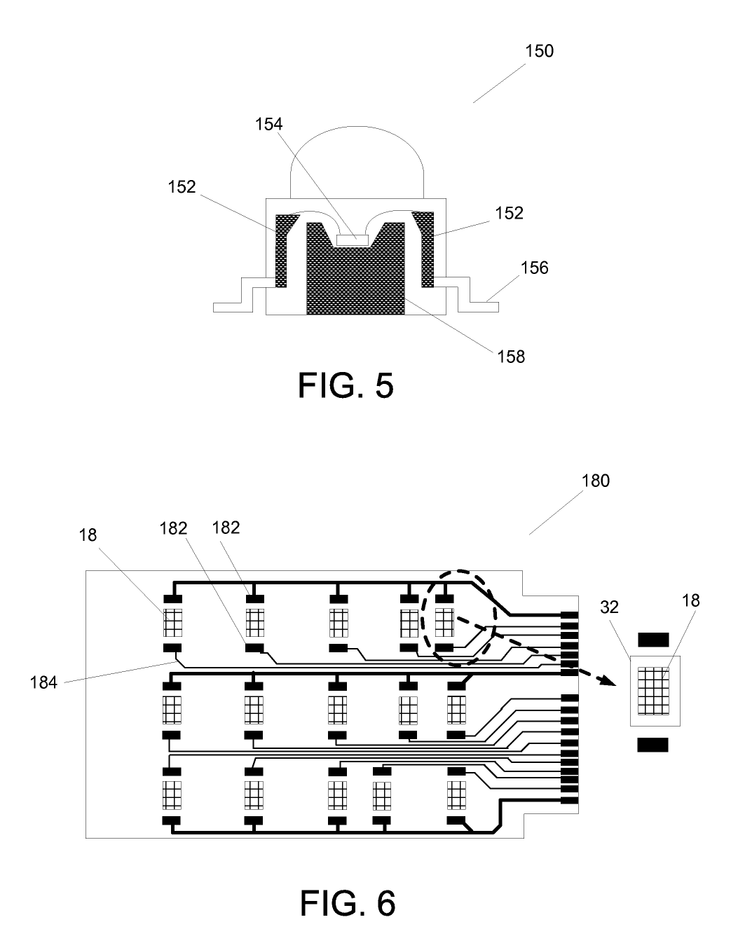

FIG. 5 is a cross sectional view of one of the LED component 150. LED die 154 has PN connections 152 which are extended externally in a form of electrical leads 156 for further electrical connection with the circuit pad located on a printed wiring board. Majority of the heat is generated at the LED Die. For efficient heat dissipation LED die 154 is thermally coupled with the thermal slug 158 which further conducts heat to the printed wiring board.

FIG. 6 is a schematic top view of an outermost patterned circuit layer in accordance with an embodiment of the present invention where sinkpad locations 18 are shown. Circuit layer 180 represents top view of the printed wiring board of the present invention. Circuit pads 182 are the electrical connection points for the LED leads. Sinkpads 18 are strategically located at each LED locations for efficient thermal coupling. A window opening 32 is an opening where portions of the dielectric layer and circuit layer are removed prior to the lamination process such that the embossed sinkpad 18 can come through from the back side of the printed circuit board to the top side of the circuit board. An opening 32 is located at each sinkpad location. Preferably size of an opening 32 is larger than the size of the sinkpad 18. Circuit traces 184 further connects multiple LED components together.

### Materials Used for the Thermally Conductive Layer

A variety of materials can be used in the construction of thermally conductive layer of a thermally efficient PWB in accordance with embodiments of the invention. In many embodiments the thermally conductive layer is chosen from aluminum, aluminum alloys, copper, Aluminum Nitride, Aluminum Silicon Carbide, C—SiC (Carbon-Silicon Carbide), metal matrix, metal alloys, metal, carbon, metal-carbon-metal, carbon composites, graphite, metal-graphite-metal, graphite composites, flexible graphite, carbon nanotube composites, thermally conductive polymer and thermally conductive molding compound. Any material that has thermal conductivity in excess of 5 W/m.k can be used in the construction of a thermally conductive layer in accordance with embodiments of the invention. In one of the preferred embodiment of the present invention any thermally conductive material that can change its original shape under force without loosing its material integrity can be used for thermally conductive layer. For example an aluminum or copper.

In a broad sense, any combination of the materials described above can be used in the construction of a thermally conductive layer where later a sinkpad can be formed, preferably a hollow sinkpad.

Manufacturing Process Steps for Constructing Thermally Efficient PWB that has a Hollow Sinkpad

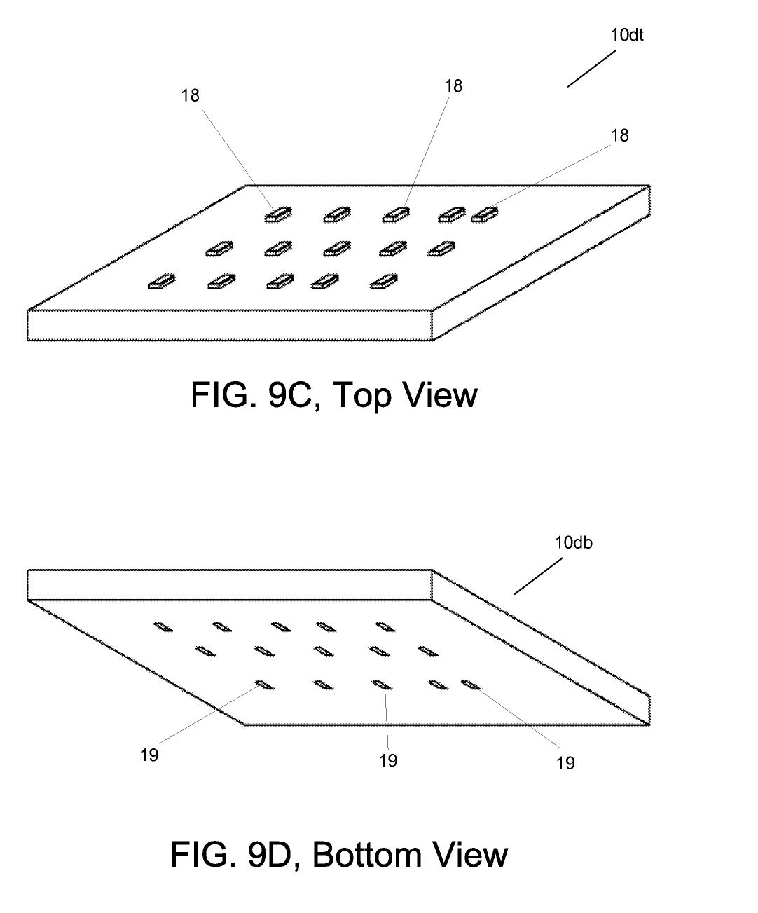

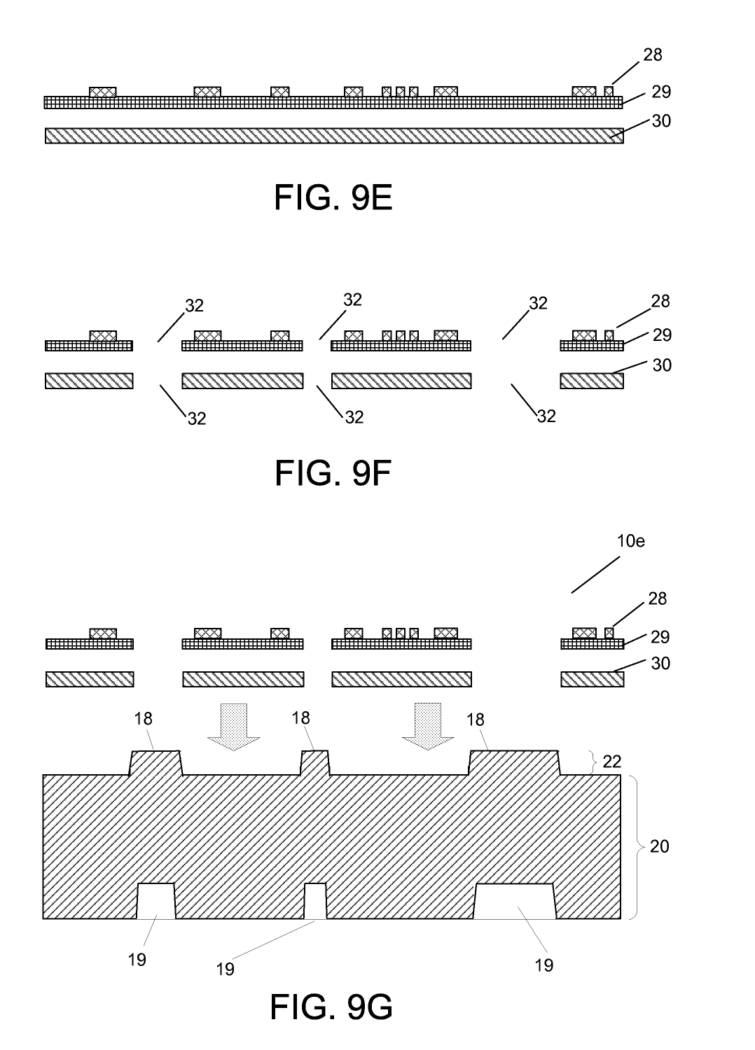

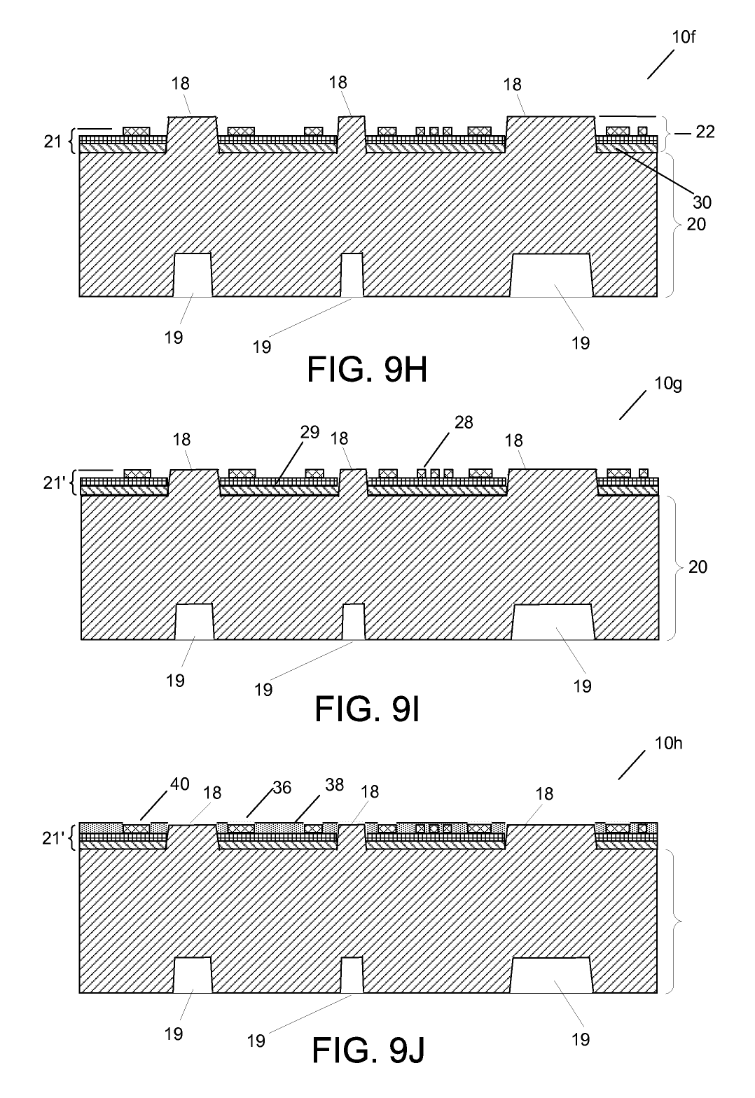

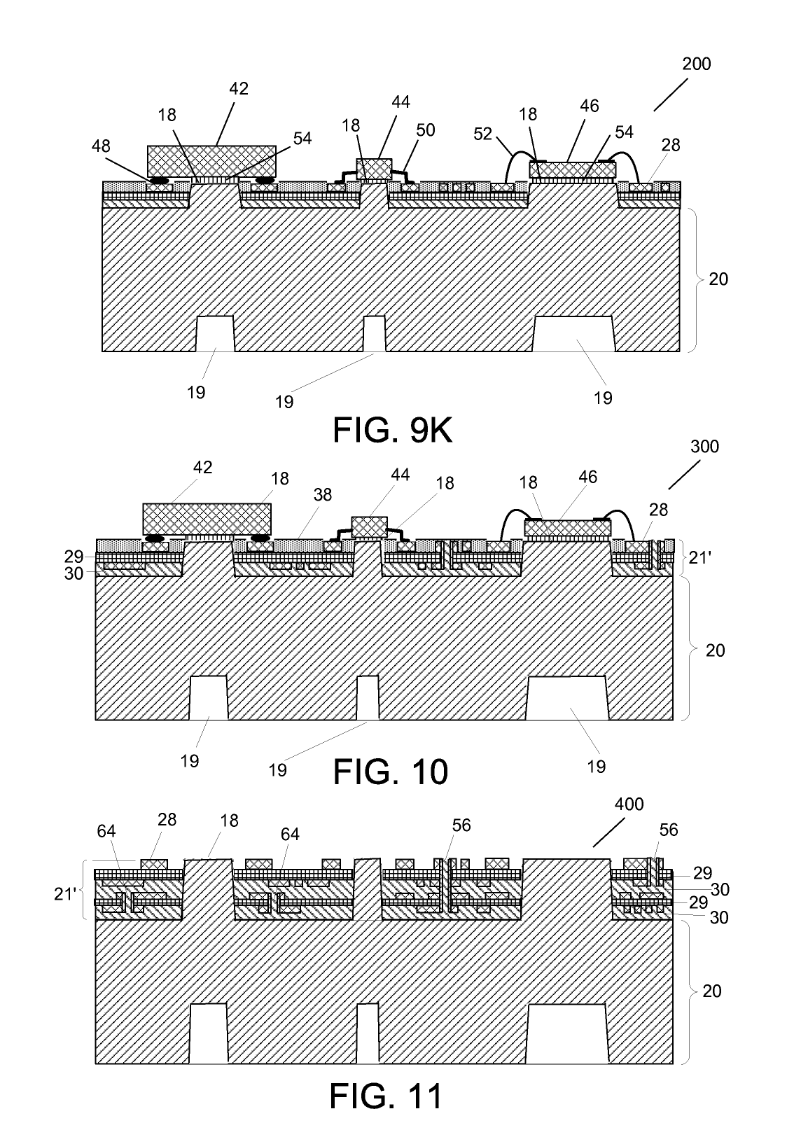

Manufacturing processes and tools used to manufacture a thermally efficient PWB in accordance with an embodiment of the present invention are illustrated in FIGS. 9A-9K.

First, as shown in FIG. 9A, a thermally conductive layer 12 is prepared. In several embodiments, the thermally conductive layer 12 is selected from the list of materials described above. In one of the preferred embodiment of the present invention, the thermally conductive layer 12 is copper. In another preferred embodiment of the invention, the thermally conductive layer 12 is aluminum such as 5052 grade aluminum alloy. Copper has better thermal conductivity than the aluminum but copper is heavier and more expensive than the aluminum. Sometimes, aluminum is more preferred over copper to save weight and/or cost of the LED system. Another thermally conductive material, graphite and carbon, is getting popular due to its high thermal conductivity, higher rigidity, low CTE and light weight.

In the illustrated embodiment 10a a thermally conductive layer 12 that includes aluminum alloy is prepared. In one embodiment the thermally conductive layer 12 is an aluminum sheet having a minimum thickness of 1 mil (0.001 inch). In one preferred embodiment the aluminum sheet has a thickness between 5 mil and 250 mil. In one most preferred embodiment the aluminum sheet has a thickness between 20 mil and 125 mil.

Though Aluminum and Aluminum alloys are preferred material to use as the thermally conductive layer 12 in the present invention, aluminum materials are not compatible with solder. Additional surface preparation is necessary to make the aluminum surface compatible with solder. It is desirable to provide a top surface on the sinkpad that is compatible with a solder reflow process to minimize thermal resistance between an LED and the thermally conductive layer 12. In one embodiment aluminum surface preparation is done prior to the sinkpad forming step. In other embodiments surface preparation of the aluminum is done after the sinkpad forming step. Preferred surface preparation includes any of nickel plating, copper plating, nickel flash followed by the copper plating, electroless nickel followed by electrolytic nickel plating and then by electrolytic copper or a similar process that can make the surface of the thermally conductive layer 12 compatible with the solder. Although the foregoing examples are for aluminum material, one of ordinary skill in the art will recognize that similar surface preparation is required if a thermally conductive material used for the thermally conductive layer 12 is not compatible with the solder.

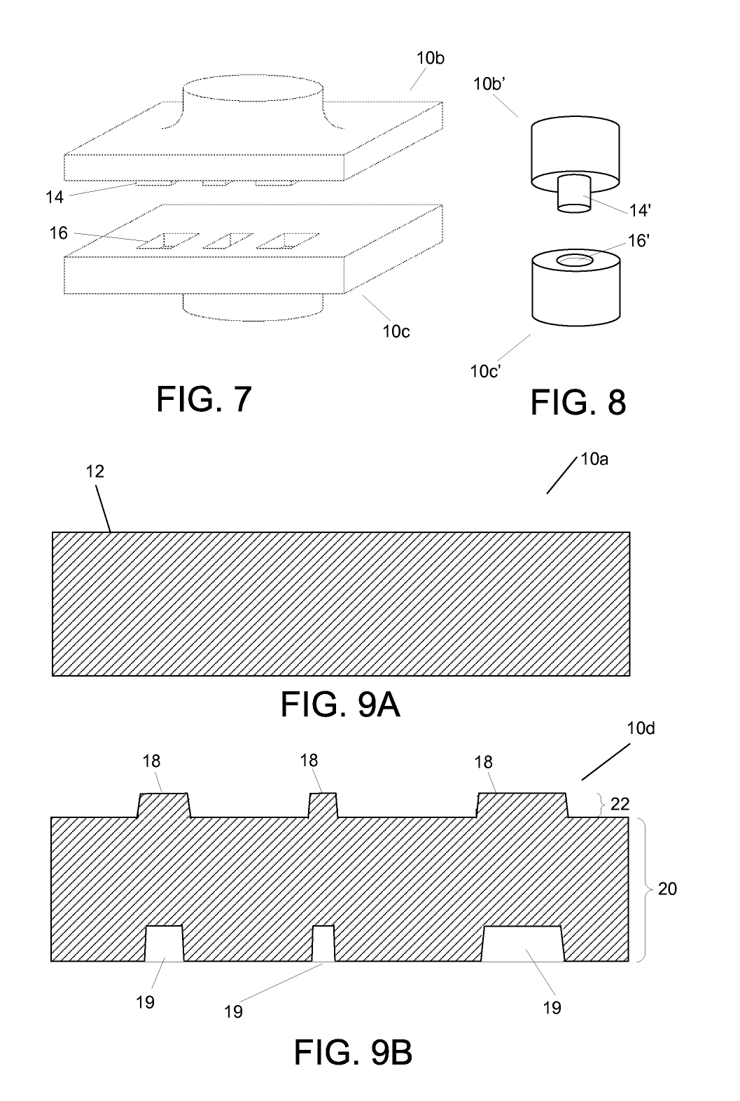

A forming tool in accordance with the present invention is shown in FIG. 7. In this illustration forming tool is made up of the male and female die. In one embodiment the forming tool has more than one forming features on the same tool. The male die 10b has raised feature 14 and female die 10c has cavity feature 16. It is also known as hard tool. The forming tool can be made from hardened steel. Material other than steel can also be used. A size of the male feature 14 is smaller than the size of the cavity feature 16. The height of the male feature 14 and depth of the female feature 16 is determined by the height requirement of the sinkpad. In one embodiment, male female die can be flat bed type. In other embodiments male female die can be continuous drum roll type.

In one embodiment the forming tool is a half-shear type forming tool having a relatively small size difference between the male feature 14 and the cavity feature 16. A half-shear forming tool will shear or form an opening if pressed sufficiently far into the material. If the penetration of the male feature 14 of the forming tool is limited, generally to half the thickness of the material or less, the material will be embossed with a relatively sharp edge on the raised portion. This may provide a sinkpad with a large flat surface to thermally couple with a thermal slug soldered to the sinkpad.

Another forming tool in accordance with the present invention is shown in FIG. 8. In this illustration the forming tool is made up of a male and female die. In one preferred embodiment the forming tool has one forming feature on the tool. The male die 10b′ has raised feature 14′ and female die 10c′ has cavity feature 16′. The forming tool can be made from hardened steel. Material other than steel can also be used. A size of the male feature 14′ is smaller than the size of the female cavity feature 16′. The forming tool may be a half-shear type forming tool. The height of the male feature 14′ and depth of the female feature 16′ is determined by the height requirement of the sinkpad. In a preferred embodiment a single featured tool can be used for a CNC turret embossing process. CNC embossing using single feature tool is advantageous. It gives design flexibility with easy to make design modifications unlike hard tool embossing. A CNC turret press can handle several single featured tools at a time to form various features on the thermally conductive layer of the present invention.

The sinkpad is formed on to the thermally conductive layer 10d using an embossing tool as shown in FIG. 9B. The male part of the tool 14 or 14′ presses a portion of the thermally conductive layer in a plane normal to the surface spreading direction of the thermally conductive layer. The female part of the tool 16 or 16′ allows the male part of the tool 14 or 14′ to press a portion of the thermally conductive layer in a plane normal to the surface spreading direction of the thermally conductive layer in a controlled shape. Due to the forming process sinkpads have two sides—a top side and a bottom side where the sinkpad is a hollow in shape. In the illustrated embodiment 10d a top side 18 is a raised side of the thermally conductive layer and a bottom side 19 is a depressed side of the thermally conductive layer. The base thickness 20 is same as the starting thickness of the thermally conductive layer. The height 22 of the sinkpad is determined by the total thickness of a dielectric layer and a circuit layer required building a thermally efficient PWB of the present invention.

In one embodiment of the present invention the height 22 of the sinkpad is equal to the combined thickness of the dielectric layer and the circuit layer required on the raised side of the sinkpad to build a thermally efficient PWB. In one preferred embodiment of the present invention the height 22 of the sinkpad is equal to more than the combined thickness of the dielectric layer and the circuit layer required on the raised side of the sinkpad to build a thermally efficient PWB. In one embodiment the height of the sinkpad is a minimum of 10 mil (0.010 inch) more than the combined thickness of the dielectric layer and the circuit layer required on the raised side of the sinkpad to build a thermally efficient PWB. In one preferred embodiment the height of the sinkpad is a minimum of 5 mil (0.005 inch) more than the combine thickness of the dielectric layer and the circuit layer required on the raised side of the sinkpad to build a thermally efficient PWB. In one most preferred embodiment the height of the sinkpad is a minimum of 1 mil (0.001 inch) more than the combined thickness of the dielectric layer and the circuit layer required on the raised side of the sinkpad to build a thermally efficient PWB.

In one embodiment the combined thickness of the dielectric layer and the circuit layer is the calculated thickness of the material prior to the lamination process. In another embodiment the combined thickness of the dielectric layer and the circuit layer is the calculated thickness of the material after the lamination process.

FIG. 9C is a pictorial top view of an embossed 1 mm thick aluminum plate 10dt. Features 18 are raised sides of the embossed sinkpad. Illustrated sinkpad height is 5 mil. FIG. 9D is a pictorial bottom view of an embossed 1 mm thick aluminum plate 10db. Features 19 are depressed sides of the embossed sinkpad. FIG. 9C and FIG. 9D shows a total of 15 sinkpads on an aluminum layer. In one embodiment all 15 sinkpads are formed at once with a hard tool die similar to the die 10b, 10c shown in FIG. 7. In other preferred embodiments the 15 sinkpads are embossed one at a time on a CNC turret press using a single feature tool 10b′, 10c′ of the type shown in FIG. 8.

A bond promoting surface treatment is applied to the formed thermally conductive layer for further bonding with the dielectric layer. This may be an oxidation treatment applied to the copper material on the top surface of the thermally conductive layer. In one embodiment the bond promoting surface treatment is done prior to the sinkpad forming step. In other embodiments the bond promoting surface treatment is done after the sinkpad forming step. In one embodiment of the invention surface preparation of the thermally conductive layer is done to achieve optimum bond with the dielectric layer.

It will be recognized that the bond promoting surface treatment may be incompatible with solder. It may be necessary to protect the top surface of the sinkpads from the bond promoting surface treatment. In other embodiments the bond promoting surface treatment may be removed from the top surface of the sinkpads to provide compatibility with solder. In still other embodiments a surface preparation to provide compatibility with solder that is limited to the top surface of the sinkpads may be given before the bond promoting surface treatment is applied.

In one preferred embodiment of the invention surface preparation of the thermally conductive layer is done to achieve optimum bond with the dielectric layer and to make the surface compatible with the solder reflow process. In one embodiment surface preparation of the thermally conductive layer to make the surface compatible with the solder reflow process is done on the entire thermally conductive layer. In another embodiment surface preparation of the thermally conductive layer to make the surface compatible with the solder reflow process is done only at the sinkpad locations of the thermally conductive layer. Preferred surface preparation includes nickel plating, copper plating, nickel flash followed by the copper plating, electroless nickel followed by electrolytic nickel plating and then by electrolytic copper or a similar process that can make the thermally conductive layer surface solderable.

A bond promoting surface treatment is applied to the formed thermally conductive layer for further bonding with the dielectric layer. In one embodiment, oxidation treatment is applied to the thermally conductive layer. In one embodiment bond promoting surface treatment is done prior to the sinkpad forming step. In other embodiments bond promoting surface treatment is done after the sinkpad forming step. In one embodiment of the invention surface preparation of the thermally conductive layer is done to achieve optimum bond with the dielectric layer.

Prepare a circuit layer and dielectric layer as shown in FIG. 9E. Preparation of the circuit layer includes selecting a copper clad laminate 29 and patterning the circuit 28. Preparation further includes selecting the semi cured B-stage dielectric layer 30. In several preferred embodiments, dielectric layer 30 is a low-flow or no-flow B-stage dielectric prepreg or bond sheet.

Remove portions of the material 32 from the laminate layer 29 and the dielectric prepreg layer 30 at the predefined sinkpad locations 18 of 10d as shown in FIG. 9F. The size of the cut-out window 32 is larger than the size of the sinkpad 18. In one embodiment cut-out window size is 20 mil to 30 mil larger than the size of the sinkpad leaving 10 mil to 15 mil clearance per side. In other preferred embodiment cut-out window size is less than 20 mil larger than the size of the sinkpad leaving less than 10 mil clearance per side. In one embodiment size of the cut-out window in laminate layer 29 is smaller than the size of the cut-out window in dielectric layer 30. In other embodiment size of the cut-out window in laminate layer 29 is equal to the size of the cut-out window in dielectric layer 30. Removal of the material in accordance with embodiments of the invention can be done by mechanical drilling, laser drilling, laser cutting, CNC routing, die cutting, punching, high pressure water jet cutting or equivalent methods. In one of the embodiments, circuit pattern 28 is formed after the lamination step. In other embodiment copper clad laminate 29 is not used instead only copper foil used for circuit layer.

Now, align and stack the embossed thermally conductive layer, the dielectric layer 30 and a patterned circuit laminate as shown in FIG. 9G. In one preferred embodiment of the present invention the height 22 of the sinkpad 18 is equal to or greater than the combined thickness 21 of the dielectric layers and the circuit layer as shown in 10f of FIG. 9H.

### Laminate Stack-Up 10f Under Temperature, Pressure and Time.

Laminated stack-up 10g is shown in FIG. 9I. The B-stage dielectric layer 30 gels and gets compressed down under the heat and pressure. Reduction in thickness can vary based on many variables such as type, thickness, manufacturer, number of prepreg ply, heat rise, pressure to name a few. The B-stage dielectric layer bonds all the layers together. The sinkpad 18 remains exposed on the surface through the removed portions of the dielectric layers. The hollow nature of the heatsink pad 18 and the conforming nature of the thermally conductive material allows the heatsink pad to get compressed under pressure during lamination process making it substantially coplanar with the circuit layer.

The post lamination height 22′ of the sinkpad 18 is less than the pre-lamination sinkpad height 22. The post lamination combined thickness 21′ of the dielectric layer and the circuit layer is smaller than the pre-lamination combined thickness 21 of the dielectric layer and the circuit layer. Post lamination height of the sinkpad 22′ and post lamination combined thickness of the dielectric layer and circuit layer 21′ are substantially same. On one preferred embodiment post lamination height of the sinkpad and post lamination combined thickness of the dielectric layer and circuit layer are within +/−5 mil (0.005 inch) tolerance. In one preferred embodiment sinkpad surface and the outermost circuit layer surface are substantially coplanar.

In one of the most preferred embodiment the hollow sinkpad is advantageous to manufacture uniform, cost effective and consistent coplanar surface with the circuit layer. This is the biggest manufacturing advantage hollow sinkpad brings compared to a solid sinkpad (For example solid sinkpad manufactured by Injection molding, forging or chemical etching etc.). The hollow sinkpad has an unfilled space 19 underneath so it can be pressed down without damaging the lamination apparatus. Hollow sinkpad embodiments bring many manufacturing advantages such as, any thermally conductive material that can change its original shape under force without loosing its material integrity can be used; Uneven heights of the sinkpads over larger panel can be reset to even level without damaging lamination apparatus; no need to remove or add any material to form the sinkpad i.e. it eliminates additive or subtractive process; no wastage of the material; resulting lower cost, consistent co-planarity between the sinkpad and a circuit layer, thus higher yield. Apply solder mask 38 to cover circuits leaving some opening 40 as shown in FIG. 9J. Finish rest of the fabrication process to complete thermally efficient printed wiring board 10h according to the one of the preferred embodiment of the present invention.

One of the preferred embodiments of a thermally efficient printed wiring board assembly in accordance with the present invention is shown in FIG. 9K. As illustrated, the LED components are thermally and electrically coupled with the thermally efficient printed wiring board. In one of the preferred embodiments, LED components are electrically coupled with the circuit pad 28 and thermally coupled with sinkpad 18 where circuit pad and sinkpad are substantially coplanar. In another embodiment, LED components are electrically coupled with the circuit pad 28 and thermally coupled with sinkpad 18 where circuit pad and sinkpad are somewhat coplanar. In one of the preferred embodiment thermal interface material 54 is solder.

A thermally efficient PWB assembly 300 with two circuit layers is shown in FIG. 10. Height of the sinkpad 22′ is equivalent to a combined thickness of a dielectric layer 30, dielectric laminate layer 29 and circuit layers. The same process steps can be used to make multilayer thermally efficient PWB assembly 400 as shown in FIG. 11. Height of the sinkpad 22′ is equivalent to the combined thickness of the dielectric layers 30, dielectric laminate layers 29 and circuit layers. Multilayer circuits are connected from one layer to other by plated through holes 56 and 64.

Although the foregoing embodiments have been described and shown in the accompanying drawings as typical, it would be understood that additional variations, substitutions and modifications can be made to the system, as disclosed, without departing from the scope of the invention. This invention is not limited to the specific constructions and arrangements shown and described, since various other modifications may occur to those of ordinary skill in the art. The description is thus to be regarded as illustrative instead of limiting. Accordingly, the scope of the invention should be determined not by the embodiments illustrated, but by the appended claims and their equivalents.

What is claimed is:

1. A printed circuit board comprising:
a dielectric layer having a first surface and an opposing second surface and at least one cut-out window that provides an opening from the first surface to the second surface;
a circuit layer having a first surface and an opposing second surface and at least one cut-out window that provides an opening from the first surface to the second surface, the at least one cut-out window of the circuit layer corresponding to the at least one cut-out window of the dielectric layer, the first surface of the circuit layer being laminated to the first surface of the dielectric layer; and
a thermally conductive layer laminated to the second surface of the dielectric layer, the thermally conductive layer including at least one sinkpad that passes through the cut-out windows in the dielectric layer and the circuit layer, the sinkpad being an embossed, hollow feature of the thermally conductive layer.

2. The printed circuit board of claim 1 wherein the thermally conductive layer is an aluminum sheet.

3. The printed circuit board of claim 1 wherein a surface of the sinkpad is coplanar with the second surface of the circuit layer.

4. The printed circuit board of claim 1 wherein the thermally conductive layer receives a bond promoting surface treatment for further bonding with the dielectric layer.

5. The printed circuit board of claim 4 wherein the bond promoting surface treatment is selectively applied only to portions of the surface of the thermally conductive layer that bond with the dielectric layer.

6. The printed circuit board of claim 1 wherein the thermally conductive layer receives a surface preparation to make the sinkpad compatible with a solder reflow process.

7. The printed circuit board of claim 6 wherein the surface preparation is selectively applied only to portions of the surface of the thermally conductive layer that pass through the cut-out window in the dielectric layer.

8. The printed circuit board of claim 6 wherein the thermally conductive layer is an aluminum sheet and the surface preparation includes at least one of nickel plating, copper plating, nickel flash, electroless nickel, and electrolytic nickel plating.

9. A method of manufacturing a printed circuit board, the method comprising:
cutting at least one window in a dielectric layer having a first surface and an opposing second surface, the cut-out window providing an opening from the first surface to the second surface;
cutting at least one window in a circuit layer having a first surface and an opposing second surface, the cut-out window providing an opening from the first surface to the second surface;
laminating the circuit layer to the first surface of the dielectric layer such that the cut-out windows provide openings through the dielectric and circuit layers;
embossing at least one hollow sinkpad in a thermally conductive layer; and
laminating the thermally conductive layer to the second surface of the dielectric layer such that the at least one sinkpad passes through the cut-out windows in the dielectric and circuit layers.

10. The method of claim 9 wherein the thermally conductive layer is an aluminum sheet.

11. The method of claim 9 further comprising compressing the dielectric layer, the circuit layer, and the thermally conductive layer to make a surface of the sinkpad coplanar with a component mounting surface of the circuit layer.

12. The method of claim 9 further comprising treating the thermally conductive layer to create a bond promoting surface for further bonding with the dielectric layer.

13. The method of claim 12 wherein only portions of the surface of the thermally conductive layer that bond with the dielectric layer are treated to create the bond promoting surface.

14. The method of claim 9 further comprising treating the thermally conductive layer to prepare a sinkpad surface that is compatible with a solder reflow process.

15. The method of claim 14 wherein only the sinkpad surface of the thermally conductive layer is treated to make the sinkpad compatible with a solder reflow process.

16. The method of claim 14 wherein the thermally conductive layer is an aluminum sheet and treating the thermally conductive layer includes at least one of nickel plating, copper plating, nickel flash, electroless nickel, and electrolytic nickel plating.

17. An electronic assembly comprising:
a printed circuit board that includes
a dielectric layer having a first surface and an opposing second surface and at least one cut-out window that provides an opening from the first surface to the second surface,
a circuit layer having a first surface and an opposing second surface and at least one cut-out window that provides an opening from the first surface to the second surface, the at least one cut-out window of the circuit layer corresponding to the at least one cut-out window of the dielectric layer, the first surface of the circuit layer being laminated to the first surface of the dielectric layer, and
a thermally conductive layer laminated to the second surface of the dielectric layer, the thermally conductive layer including at least one sinkpad that passes through the cut-out windows in the dielectric layer and the circuit layer, the sinkpad being an embossed, hollow feature of the thermally conductive layer; and
a heat generating electronic component having electrical terminals electrically coupled to the circuit layer and a thermal slug thermally coupled to the sinkpad of the thermally conductive layer.

18. The electronic assembly of claim 17 wherein the heat generating electronic component is a light emitting diode (LED).

19. The electronic assembly of claim 17 wherein the thermally conductive layer is an aluminum sheet.

20. The electronic assembly of claim 17 wherein a surface of the sinkpad is coplanar with the second surface of the circuit layer.

21. The electronic assembly of claim 17 wherein the thermally conductive layer includes a prepared sinkpad surface that is compatible with a solder reflow process.

22. The electronic assembly of claim 21 wherein the prepared sinkpad surface includes only portions of the surface of the thermally conductive layer that pass through the cut-out windows in the dielectric layer and the circuit layer.

23. The electronic assembly of claim 21 wherein the thermally conductive layer is an aluminum sheet and the prepared sinkpad surface includes at least one of nickel plating, copper plating, nickel flash, electroless nickel, and electrolytic nickel plating.
